(19) United States
(12) Patent Application Publication
(10) Pub. No.: US 2024/0055501 A1
(43) Pub. Date: Feb. 15, 2024

(54) SEMICONDUCTOR DEVICE STRUCTURE AND MANUFACTURING METHOD THEREOF

(71) Applicant: Taiwan Semiconductor Manufacturing Company, Ltd., Hsinchu (TW)

(72) Inventors: Pinyen Lin, Rochester, NY (US); Chung-Liang Cheng, Changhua County (TW); Lin-Yu Huang, Hsinchu (TW); Li-Zhen Yu, New Taipei City (TW); Huang-Lin Chao, Hillsboro, OR (US)

(73) Assignee: Taiwan Semiconductor Manufacturing Company, Ltd., Hsinchu (TW)

(21) Appl. No.: 17/887,487

(22) Filed: Aug. 14, 2022

(51) Int. Cl. H01L 29/45; H01L 29/06; H01L 29/08; H01L 29/423; H01L 29/417; H01L 29/786; H01L 29/775; H01L 21/285; H01L 29/66

(52) U.S. Cl. CPC H01L 29/45; H01L 29/0673; H01L 29/0847; H01L 29/42392; H01L 29/41733; H01L 29/78696; H01L 29/775; H01L 21/28518; H01L 29/66742; H01L 29/66439

(57) ABSTRACT

A semiconductor device and the manufacturing method thereof are described. The device includes semiconductor channel sheets, source and drain regions and a gate structure. The semiconductor channel sheets are arranged in parallel and spaced apart from one another. The source and drain regions are disposed beside the semiconductor channel sheets. The gate structure is disposed around and surrounding the semiconductor channel sheets. The silicide layer is disposed on the source region or the drain region. A contact structure is disposed on the silicide layer on the source region or the drain region. The contact structure includes a metal contact and a liner, and the silicide layer is in contact with the metal contact, and the liner is separate from the silicide layer by the metal contact.

### BACKGROUND

In the manufacturing processes of integrated circuits, electronic circuits with components such as transistors are formed from semiconductor-based wafers. Continuously scaling down and high integration density of semiconductor devices have increased the complexity of semiconductor manufacturing processes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 through FIG. 23 are schematic cross-sectional views illustrating a portion of a semiconductor device at various stages of a method for forming the semiconductor device according to some embodiments of the present disclosure.

FIG. 24 is a schematic cross-sectional view of an exemplary structure of a semiconductor device according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure. Source/drain region(s) may refer to a source or a drain, individually or collectively dependent upon the context.

Some embodiments described herein provide a semiconductor device including a backside contact with a liner selective deposited on dielectric isolation cap without contacting the silicide layer on the source and drain regions. Through the formation of a shielding layer on the silicide layer, the silicide layer and the underlying epitaxial material of the source and drain regions are well protected, and the liner is formed only on sidewalls of the contact openings but not on the silicide layer. By doing so, the contact area between the backside metal contact and the silicide layer is increased. In addition, the liner is formed selectively on the sidewalls of the contact openings without performing extra breakthrough process to remove the liner on the bottom of the opening. Accordingly, less damage to the epitaxial materials of the source and drain regions.

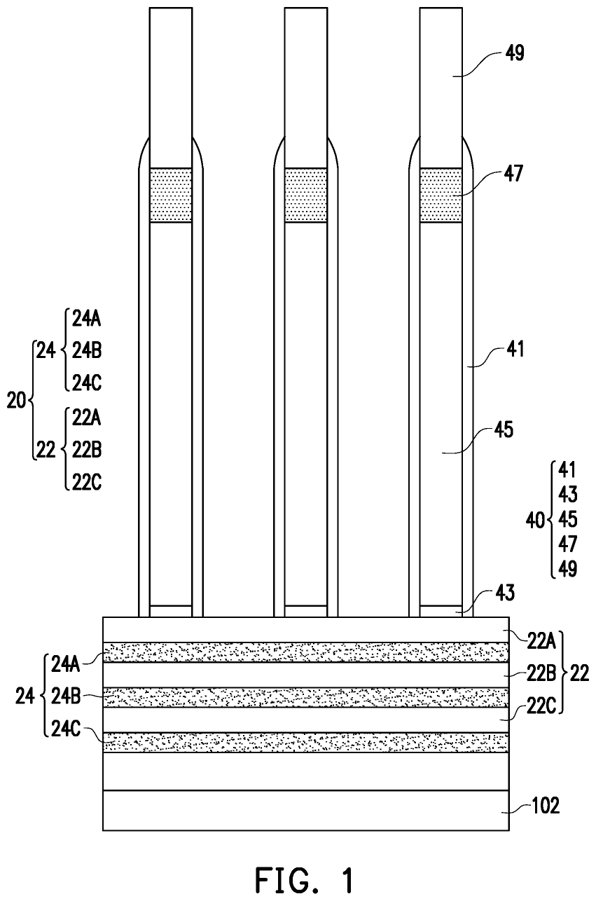

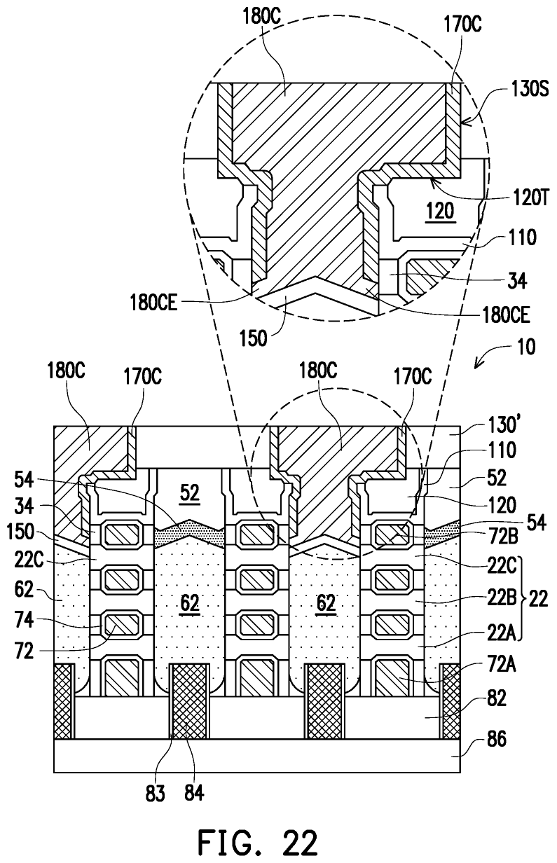

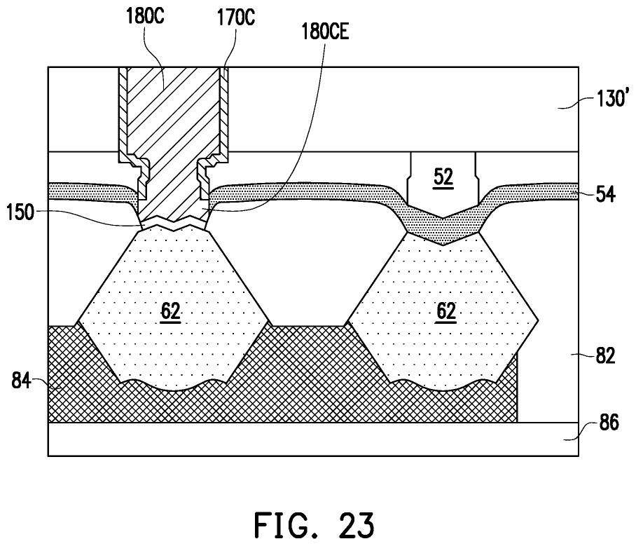

FIG. 1 through FIG. 23 are schematic cross-sectional views illustrating a portion of a semiconductor device at various stages of a method for forming the semiconductor device according to some embodiments of the present disclosure. FIGS. 22 and 23 illustrates different cross-sectional views of the semiconductor device structure 10 along orthogonal cross-sections.

Referring to FIG. 1, in some embodiments, a substrate 102 having stacks of multiple sheets (fin stacks) 20 is provided. From FIG. 1 to FIG. 21, only a portion of the device region of the device structure 1 is shown for illustration purposes. It is understood that only one fin stack is shown in FIG. 1, but multiple fin stacks are formed over the substrate 102.

Referring to FIG. 1, in some embodiments, the substrate 102 includes a semiconductor substrate. In one embodiment, the substrate 102 comprises a bulk semiconductor substrate such as a crystalline silicon substrate, and may be doped (e.g., p-type or n-type semiconductor substrate) or undoped. In one embodiment, the substrate 102 comprises a silicon-on-insulator substrate or a germanium-on-insulator substrate. In some embodiments, the substrate 102 includes a semiconductor substrate made of other suitable elemental semiconductor, such as diamond or germanium; a suitable compound semiconductor, such as gallium arsenide (GaAs), silicon carbide (SiC), indium arsenide (InAs), or indium phosphide (InP); or a suitable alloy semiconductor, such as silicon-germanium (SiGe), gallium arsenic phosphide (GaAsP), or gallium indium phosphide (GaInP).

As shown in FIG. 1, only one fin stack is shown in some embodiments, the fin stack 20 includes alternating layers of first semiconductor layers 24A-24C (collectively referred to as first semiconductor layers 24) and second semiconductor layers 22A-22C (collectively referred to as second semiconductor layers 22). In some embodiments, the first semiconductor layers 24 are formed of a first semiconductor material, the second semiconductor layers 22 are formed of a second semiconductor material, and the second semiconductor material is different from the first semiconductor material. For example, the first or second semiconductor material may include one or more selected from silicon, germanium, SiC, SiGe, GaAs, InSb, GaP, GaSb, InAlAs, InGaAs, GaSbP, GaAsSb or InP. In some embodiments, the first semiconductor layers 24 may include silicon germanium (SiGe) or the like, and the second semiconductor layers 22 may include silicon, silicon carbide, or the like. In at least one embodiment, second semiconductor layers 22 are of the same semiconductor material as the substrate 102. In a non-limiting example described herein, the second semiconductor layers 22 and the substrate 102 include silicon. In one embodiment, the first semiconductor layers 24 include SiGe, while the second semiconductor layers 22 include silicon or silicon carbide.

For example, the fin stack 20 may be formed by performing alternating epitaxial growth processes to form first semiconductor material layers (not shown) and second semiconductor material layers (not shown) in alternation, and then patterning the first and second semiconductor material layers into the first and second semiconductor layers 24 and 22 of the fin stacks 20 and patterning the substrate 102 to define the fin stacks. In some embodiments, the formation of the first or second semiconductor layer 24 or 22 may include one or more processes selected from chemical vapor deposition (CVD), atomic layer deposition (ALD), vapor phase epitaxy (VPE), molecular beam epitaxy (MBE), or the like. In some embodiments, the patterning may include one or more suitable etching processes, such as reactive ion etch (RIE), neutral beam etch (NBE), or a combination thereof. In some embodiments, isolation structures (not shown) may be included in the substrate 102 for isolation.

It is understood that the number of the semiconductor sheets is not limited by the exemplary embodiments and figures provided herein, and the fin stack 20 may include six to twenty semiconductor sheets.

Referring to FIG. 1, dummy structures 40 (including three dummy structures) are formed on the fin stack(s) 20. In some embodiments, each dummy structure 40 include a stack of a lining layer 43, a sacrificial material layer 45, a hard mask 47 and a cap mask 49 (sequentially stacked from bottom to top), and sidewall spacers 41 formed along the sidewalls of the stack. In some embodiments, several parallel dummy structures 40 are formed over and across over multiple parallel fin stacks, as the extending direction of the dummy structures is intersected with the extending direction (X-direction) of the fin stacks. In some embodiments, the spacers 41 may be a single-layer structure or a multi-layer structure made of an insulating material, such as silicon nitride (SiN), silicon oxynitride (SiON), SiCN, SiOCN, or the like.

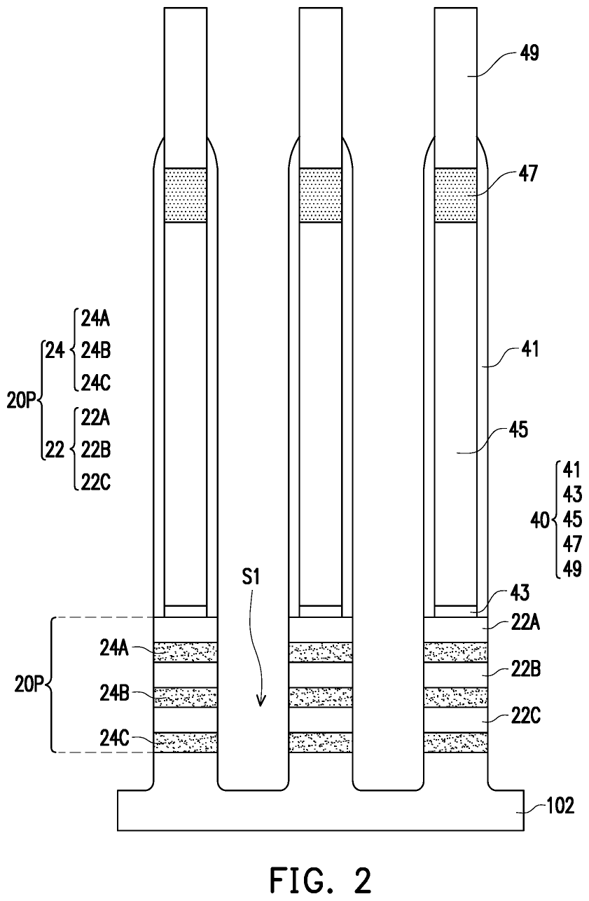

In some embodiments, as shown in FIG. 2, using the composite structure of the dummy structures 40 on the fin stacks 20 as the masks, the fin stacks 20 are patterned into the stacks 20P. That is, using the dummy structures 40 as masks, the first semiconductor layers 24 and the second semiconductor layers 22 in the respective stacks are etched. In some embodiments, the etching process includes one or more anisotropic etching processes. As the materials of the first semiconductor layers 24 and the second semiconductor layers 22 are different, the etching processes may include a series of etching processes using different etching recipes to have etch selectivity toward the predetermined materials. In some embodiments, during the patterning process, the fin stacks 20 are patterned into the stacks 20P with openings 51 there-between.

In embodiments, the stack(s) 20P has the substantially the same width as the above dummy structures 40. In some embodiments, the stacks 20P are shown in the figures to have substantially vertical sidewalls. However, it is possible that the stacks 20P may have tapered sidewalls.

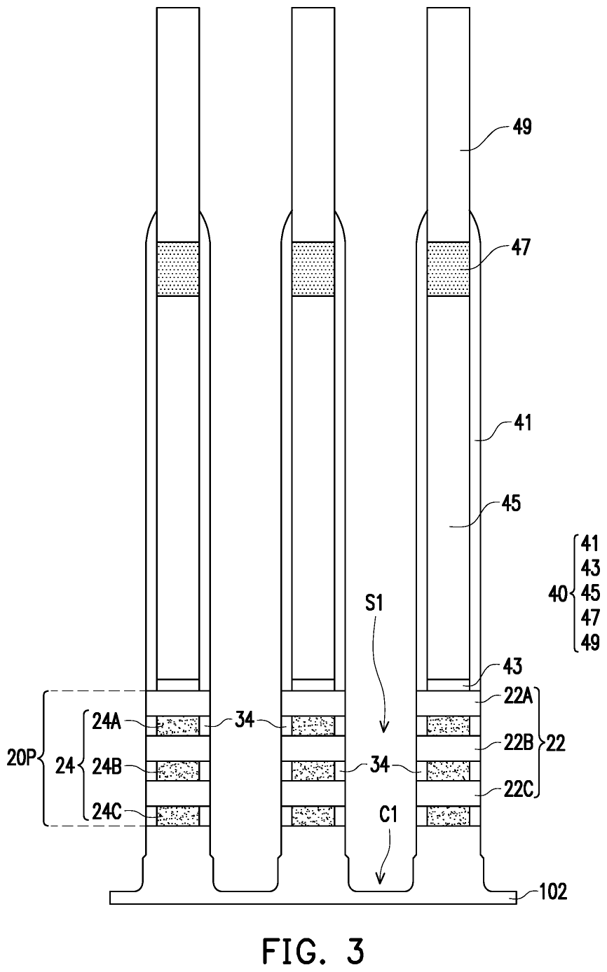

In FIG. 3, in some embodiments, lateral spacers 34 are formed by performing a lateral etching process to recess the first semiconductor layers 24 and filling up the recesses at opposite sides of the recessed first semiconductor layers 24 and between the above and below second semiconductor layers 22. In some embodiments, the lateral etching process is performed through the openings 51, and the first semiconductor layers 24 of the stacks 20P are laterally etched to form side recesses, a spacer material such as silicon nitride is filled into the side recesses by an ALD process, a CVD process, or other suitable processes and then performing at least one etching process to remove the extra spacer material by utilizing the sidewall spacers 41 as masks. In some embodiments, as seen in FIG. 3, the lateral spacers 34 are located directly below the sidewall spacers 41, and the outer sidewalls of the lateral spacers 34 and the sidewall spacers 41 are vertically aligned. In some embodiments, during the etching process, the substrate 102 may be further etched to form cavities C1 in the substrate 102.

In some embodiments, the lateral etching process may include a wet etching process by using a chemical bath with etchant(s) that selectively etches the first semiconductor layers 24 (i.e. the sacrificial semiconductor layers) with respect to the second semiconductor layers 22. In some embodiments, the first semiconductor layers 24 are sacrificial layers that will later be removed, and the second semiconductor layers 22 of the patterned stacks 20P are to form channel regions of the transistors.

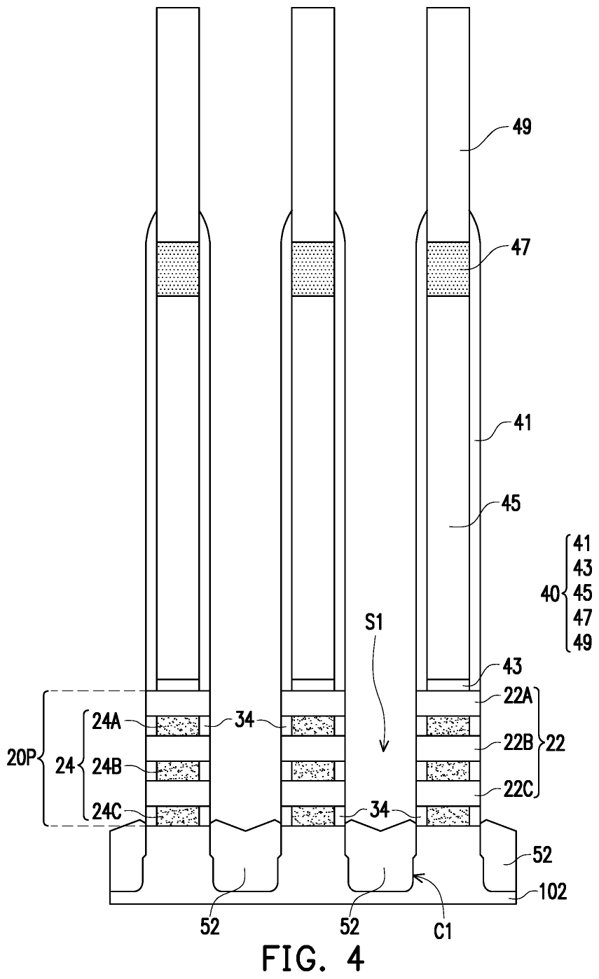

As shown in FIG. 4, a bottom-up epitaxial layer 52 is formed over the substrate 102 inside the cavities C1 and within the openings 51. In some embodiments, the bottom-up epitaxial layer 52 fills up at least the cavities C1, and the top of the epitaxial layer 52 is about at the same level of the bottom layer 24C. In some embodiments, the material of the bottom-up epitaxial layers 52 includes SiGe, SiGeB, or the like. The bottom-up epitaxial layers 52 may be formed by CVD such as atmospheric pressure CVD (APCVD), ALD, MBE, or the like.

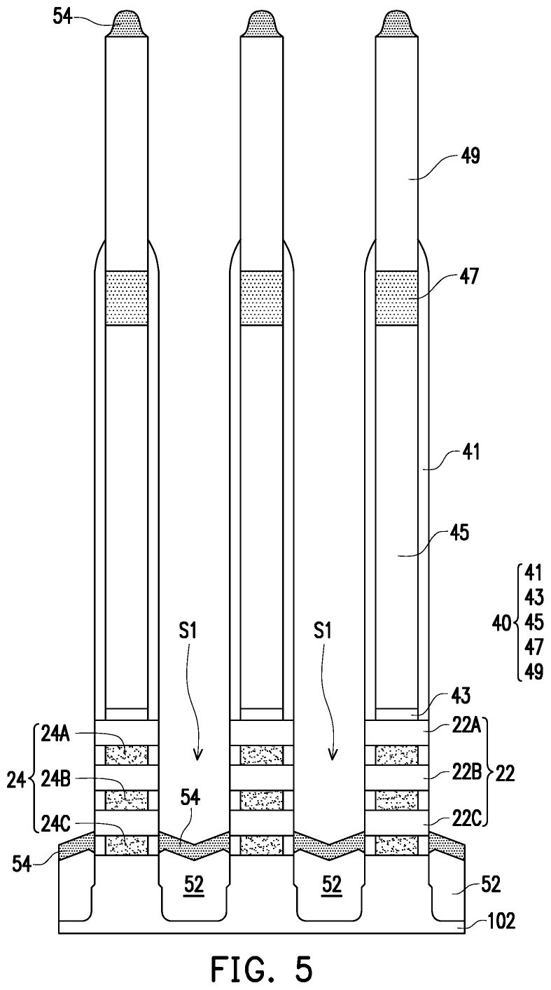

As shown in FIG. 5, an isolation material layer 54 is formed on the bottom-up epitaxial layer 52 covering the tops surface of the epitaxial layer 52. As seen in FIG. 5, in some embodiments, as the isolation material layer 54 is blanketly formed over the substrate 102, portions of the isolation material layer 54 are deposited on the cap masks 49. In some embodiments, the material of the isolation material layer 54 includes SiN, SiOC, SiCN, SiOCN, or the like. In some embodiments, the isolation material layer 54 is formed by CVD or ALD. In one embodiment, the isolation material layer 54 may have a thickness ranging from about 1 nm to about 5 nm. Afterwards, the extra portions of the isolation material layer 54 on the cap masks 49 are removed, and some parts of the cap masks 49 are removed. In some embodiments, the isolation material layer 54 may function as an etch stop layer for forming backside via or contacts.

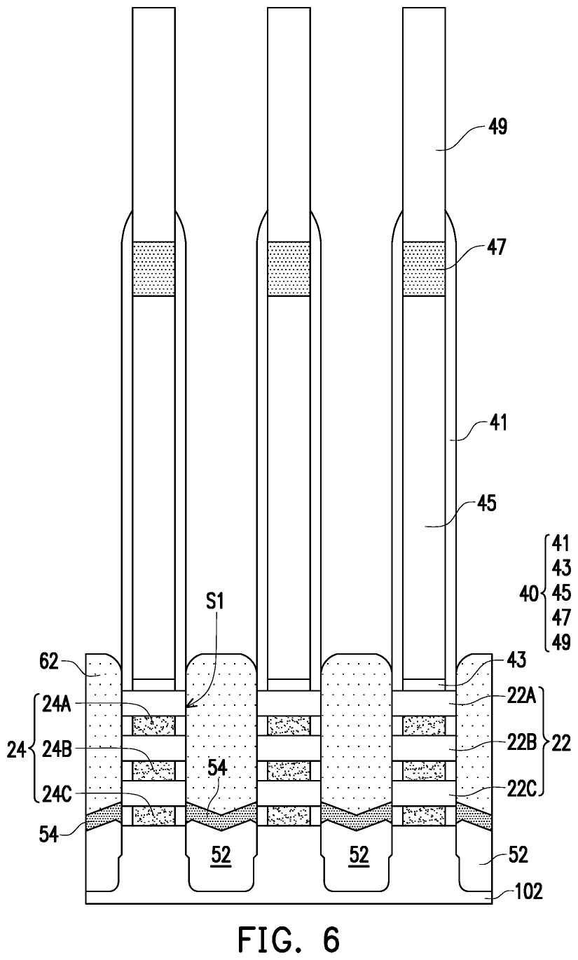

As shown in FIG. 6, in some embodiments, source and drain regions 62 are formed on the isolation material layer 54. In some embodiments, the source and drain regions 62 deposited on the isolation material layer 54 fill up the openings 51 between the adjacent stacks 20P. In some embodiments, the source and drain regions 62 are epitaxially grown from epitaxial material(s). In some embodiments, the source and drain regions 62 may exert stress to the neighboring second semiconductor layers 22 (i.e. nano-sheets 22A-22C), thereby improving performance. In some embodiments, the source and drain regions 62 are formed to be higher than the stacks 20P (i.e. higher than the top semiconductor layer 22A. In some embodiments, as seen in FIG. 6, the source and drain regions 62 are located at two opposite sides of the dummy structure 40. In some embodiments, the source and drain regions 62 are sandwiched between the sidewall spacers 41 of the two facing dummy structures 40. In some embodiments, the source and drain regions 62 are formed of epitaxial materials appropriate for either n-type or p-type transistor devices. In such embodiments, for n-type transistor devices, the materials of the source and drain regions 62 include silicon, SiC, SiCP, SiP, or the like, and for p-type devices, the materials of the source and drain regions 62 include SiGe, SiGeB, Ge, GeSn, or the like.

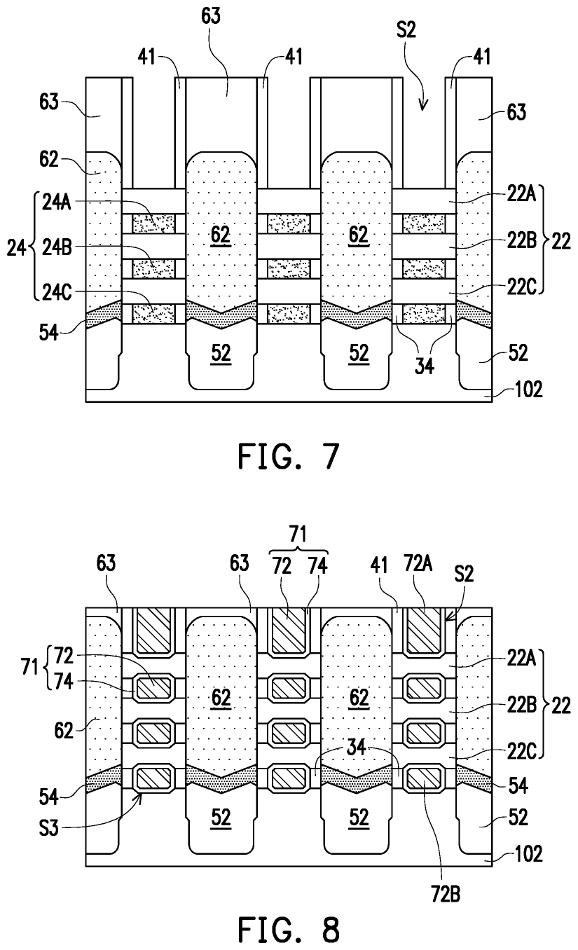

Referring to FIG. 7, in some embodiments, a dielectric interlayer 63 is formed over the substrate 102 covering the source and drain regions 62 and between the dummy structures 40. In some embodiments, the interlayer 63 includes more than one layers of dielectric materials, and the interlayer 63 may include one or more layers of silicon oxide materials and one layer of silicon nitride as an etch stop layer. In some embodiments, the interlayer 63 is formed by spin-coating, CVD, ALD, or other suitable deposition processes. Later, a planarization process is performed to partially remove the interlayer 63 and the upper portions of the dummy structures 40. In some embodiments, through the planarization process, such as chemical mechanical planarization (CMP), the masks 47 49 on the sacrificial material layer 45 and portions of the sacrificial material layer 45 and spacers 41 are removed. In some embodiments, following the planarization process, the exposed sacrificial material layers 45 are further removed through an etching process, and the lining layers 43 in the dummy structures 40 are also removed along with the removal of the sacrificial material layers 45. After the removal of the sacrificial material layers 45 and the lining layers 43, the shortened sidewall spacers 41 are remained confining void spaces S2 therebetween.

Still referring to FIG. 8, in some embodiments, the recessed first semiconductor layers 24 within the stacks 20P are removed. In some embodiments, the first semiconductor layers 24 are removed through performing a specific etching process selectively etching off the corresponding first semiconductor layers 24 with respect to the material of the lateral spacers 34. In some alternative embodiments, at least one anisotropic etching process may be performed to remove the first semiconductor layers 24. In some embodiments, the removal of the first semiconductor layers 24 of the stacks 20P leaves void spaces S3 between the second semiconductor layers 22. Based on the layout design, the void spaces S3 and the void spaces S2 may be adjoining and contiguous with each other.

Referring to FIG. 8, gate structures 71 are formed filling inside the void spaces S2 and S3. In some embodiments, a high-k dielectric layer 74 is formed conformally covering exposed surfaces of the spaces S2 and S3, and the high-k dielectric layer 74 is deposited directly on the exposed surfaces of the second semiconductor layers (i.e. semiconductor nanosheets functioning as channels) 22 are fully covered by the high-k dielectric layer 74. After forming the high-k dielectric layer 74, a gate electrode layer 72 is formed on the high-k dielectric layer 74 filling up the spaces S2 and S3. Later, the extra materials of the high-k dielectric layer 74 and the gate electrode layer 72 are removed through another planarization process. In some embodiments, the gate electrode layer 72 filled inside the spaces S2 may be referred to as the top gate electrode 72A, while the gate electrode layer 72 filled inside the spaces S2 may be referred to as the lower gate electrodes 72B.

As seen in FIG. 8, the top surfaces of the high-k dielectric layer 74 and the gate electrode layer 72 (the top electrodes 72A) are substantially flush with and levelled with the top surfaces of the remained sidewall spacers 41, and substantially flush with and levelled with the top surface(s) of the dielectric interlayer 63.

In some embodiments, the high-k dielectric layer 74 includes one or more layers of a high-k dielectric material, such as hafnium oxide, HfSiO, HfSiON, HfTaO, HMO, HfZrO, zirconium oxide, aluminum oxide, titanium oxide, hafnium dioxide-alumina alloy, other suitable high-k dielectric materials, and/or combinations thereof. In some embodiments, the high-k dielectric layer 74 is be formed by CVD, ALD, or any suitable method. In some embodiments, the material of the gate electrode layer 72 includes titanium (Ti), tungsten (W), vanadium (V), niobium (Nb), manganese (Mn), molybdenum (Mo), nitrides thereof or combinations thereof. In some embodiments, the material of the gate electrode layer 72 includes titanium nitride (TiN). In some embodiments, the material of the gate electrode layer 72 includes tungsten. For example, the gate electrode layer 72 can be deposited using physical vapor deposition (PVD), ALD, CVD, or other suitable deposition processes.

In some embodiments, through the process steps described above, a gate-all-around field effect transistor (GAA FET) structure is formed. However, it is understood that the GAA FET structure is exemplary and different transistor structures, such as fin-shaped field effect transistor (FinFET) or forksheet FET, complementary FET (CFET), may be applicable.

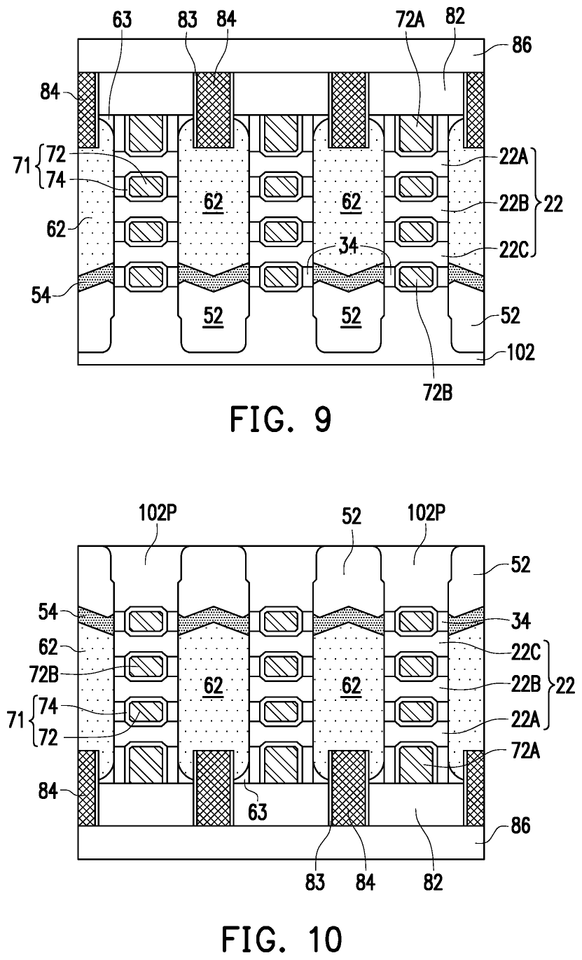

As shown in FIG. 9, an interlayer dielectric (ILD) layer 82 is formed over the substrate 102 covering the gate structures 71 and the interlayer 63. In some embodiments, the ILD layer 82 functions as a cap or an isolation lid to isolate the gate structure 71. Later, metallic contacts 84 are formed penetrating through the ILD layer 82 and reaching the source and drain regions 62. In some embodiments, the metallic contacts 84 also include barrier layers 83 and function as source and drain contacts. In some embodiments, another dielectric ILD layer 86 may be formed.

In some embodiments, the material of the ILD layer 82 or the dielectric ILD layer 86 include silicon oxide or a low-k dielectric material. For example, the low-k dielectric material may include SiON, phosphosilicate glass (PSG), borosilicate glass (BSG), borophosphosilicate glass (BPSG), undoped silicate glass (USG), fluorinated silicate glass (FSG), SiOC, spin-On-Glass (SOG), or combinations thereof. In some embodiments, the ILD layer 82 or 86 may be formed by spin-on coating, CVD, flowable CVD (FCVD), PECVD, PVD, or the like. In some embodiments, the barrier layer 83 may improve the adhesion between the metallic contacts and the ILD layer 82 and prevent diffusion. In some embodiments, the material of the barrier layer 83 includes TiN, TaN, TaAlN, TiAlN, AlN, or the like, and the material of the metallic contact 84 includes W, Co, Ru, Ir, Mo, Cu, Al, combinations thereof, or the like.

Referring to FIG. 9 and FIG. 10, the structure is flipped upside down, and a thinning process is performed to thin down the substrate 102 from the backside until the bottom-up epitaxial layer 52 is exposed. In some embodiments, the thinning process includes an etching process, a polishing process or a combination thereof. After the thinning process, the remained portions 102P of the substrate 102 on the gate structures 71 (on the gate electrodes 72B) are remained but the substrate 102 on the bottom-up epitaxial layer 52 is removed to expose the bottom-up epitaxial layer 52. After flipping over the structure, the gate electrodes 72B are located above the gate electrodes 72A.

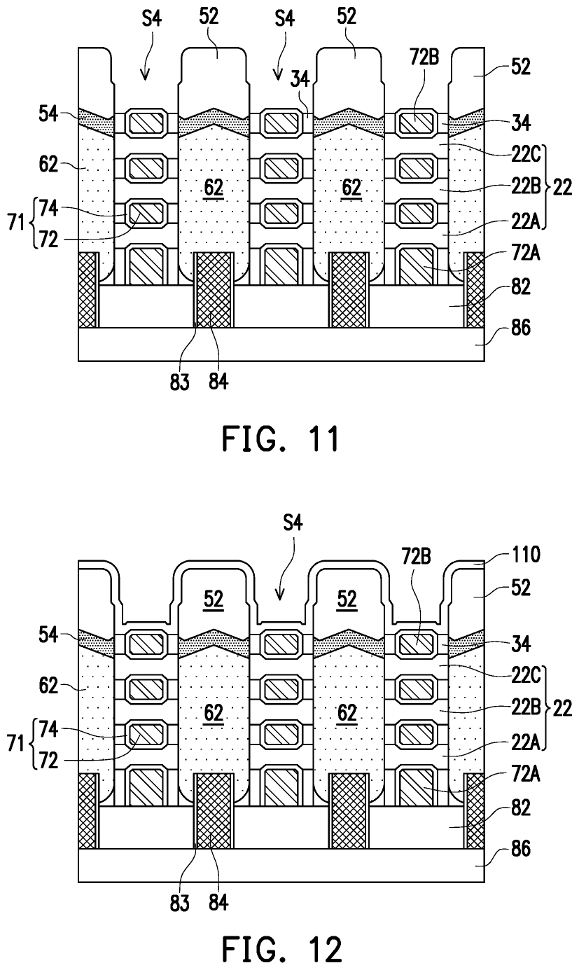

Referring to FIG. 10 and FIG. 11, the remained portions 102P of the substrate 102 on the gate structures 71 are removed through a selective etching process, and trench openings S4 are formed between the bottom-up epitaxial layer 52. In some embodiments, the portions 102P of the substrate 102 are selectively etched off, and the spacers 34 and the gate structures 71 (including the high-k dielectric layer 74 and the gate electrode layer 72) are not removed. Accordingly, the spacers 34, the high-k dielectric layer 74 around the gate electrode 72B are exposed through the openings S4 defined by the sidewalls of the bottom-up epitaxial layer 52.

As shown in FIG. 12, a liner layer 110 may be deposited over the exposed epitaxial layer 52 and over the openings S4 covering the epitaxial layer 52 and the exposed high-k dielectric layer 74 around the gate electrode 72B and the spacers 34. In some embodiments, the liner layer 110 may be conformally deposited over the openings S4 covering the exposed surfaces and the sidewalls of the bottom-up epitaxial layer 52, without filling up the openings S4. In some embodiments, the material of the liner layer 110 includes SiN, SiCN, or a combination thereof. In some embodiments, the liner layer 110 is formed PVD, CVD, ALD, or the like. In some embodiments, the liner layer 110 may have a thickness ranging from about 1 nm to about 5 nm.

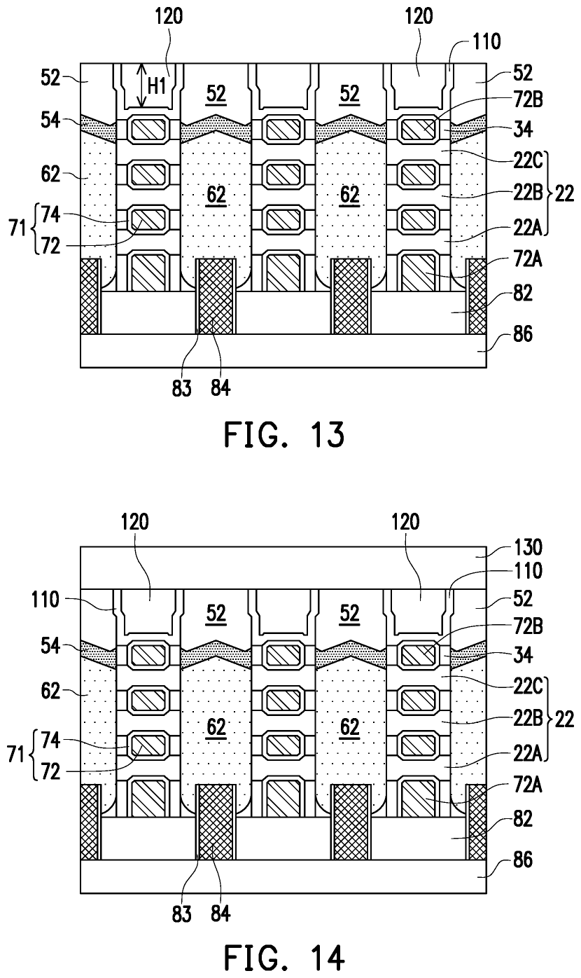

As shown in FIG. 13, a filling layer 120 is formed over the liner layer 110 and filling up the openings S4. In some embodiments, the material of the filling layer 120 includes silicon oxide, SiOC, SiCN, SiOCN, aluminum oxide, AlON, zirconium oxide (ZrO), hafnium oxide, titanium oxide, ZrAlO, zinc oxide, or a combination thereof. In some embodiments, the filling layer 120 is deposited by PVD, CVD, ALD, or the like. In some embodiments, a planarization process may be performed to remove extra materials of the liner layer 110 and the filling layer 120, so that the top surfaces of the bottom-up epitaxial layer 52, the liner layer 110, and the filling layer 120 are substantially levelled. In some embodiments, the filling layer 120 filled inside the openings S4 have a height H1 ranging from about 10 nm to about 40 nm. In some embodiments, the filling layer 120 together with the liner layer 110 functions as a back cap or an isolation lid to isolate the gate structure(s) 71.

As shown in FIG. 14, a backside hard mask layer 130 is formed over the planarized epitaxial layer 52, the liner layer 110, and the filling layer 120. In some embodiments, the backside hard mask layer 130 is blanketly formed over the planarized surfaces of the bottom-up epitaxial layer 52, the liner layer 110, and the filling layer 120. In some embodiments, the material of the backside hard mask layer 130 includes silicon oxide, SiOC, SiCN, SiOCN, aluminum oxide, AlON, zirconium oxide (ZrO), hafnium oxide, titanium oxide, ZrAlO, zinc oxide, or a combination thereof. In some embodiments, the materials of the backside hard mask layer 130 and the filling layer 120 are different. In some embodiments, the backside hard mask layer 130 is formed by PVD, CVD, ALD, or the like.

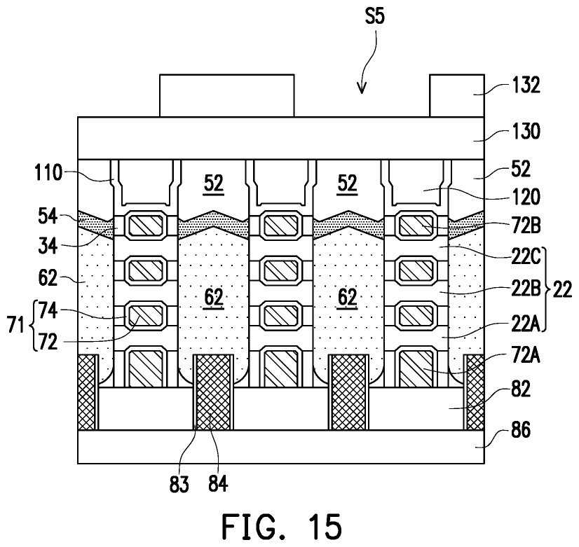

As shown in FIG. 15, a mask pattern 132 with openings S5 is formed on the backside hard mask layer 130. In some embodiments, the openings S5 of the mask pattern 132 expose the backside hard mask layer 130.

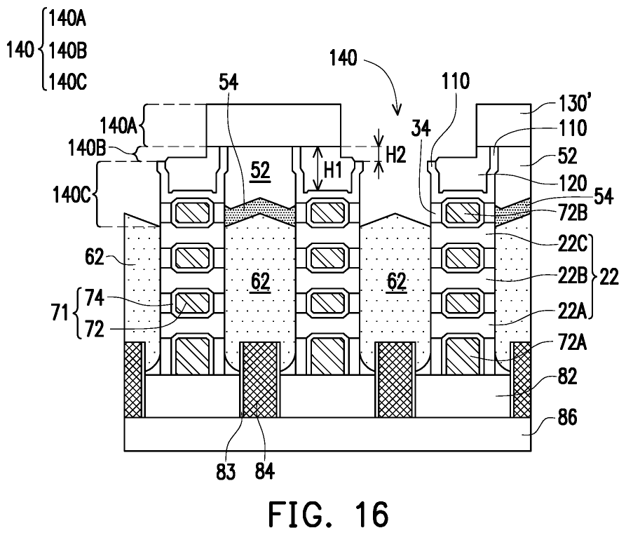

Referring to FIG. 15 and FIG. 16, through the openings S5, an etching process is performed to pattern the backside hard mask layer 130, and the underlying the epitaxial layer 52 and the isolation material layer 54 below the openings S5 are removed until the source and drain regions 62 are exposed. In some embodiments, during the etching process, the backside hard mask layer 130 is patterned to become the patterned hard mask layer 130′ and portions of the filling layer 120 and the liner layer 110 below the openings S5 are removed. That is, the filling layer 120 and the liner layer 110 below the openings S5 (exposed by the patterned hard mask layer 130′) are further recessed with a reduced height/thickness H2. In one embodiment, the recessed region may have a height H2 along the Z-direction ranging from about 1 nm to about 20 nm. In some embodiments, after the etching process, the mask pattern 132 is removed. As seen in FIG. 16, after the etching process, openings 140 are formed exposing the source and drain regions 62. In some embodiments, the etching process includes a dry etching process and/or a wet etching process.

In some embodiments, as seen in FIG. 16, the opening 140 includes a top opening 140A defined by the patterned har mask layer 130′, a bottom opening 140C defined by the recesses liner layer 110, the lateral spacers 34 and the exposed source/drain regions 62, and a middle opening 140B connecting the top and bottom openings 140A and 140C. In some embodiments, the recessed filling layer 120, the liner layer 110 and the lateral spacers 34 are exposed and top surfaces of the source and drain regions 62 are exposed. As seen in FIG. 16, the openings 140 are formed near the gate electrode 72B (the lowest gate electrode 72B) to expose the source and drain region from the backside of the structure, and the openings 140 may be referred to as backside openings.

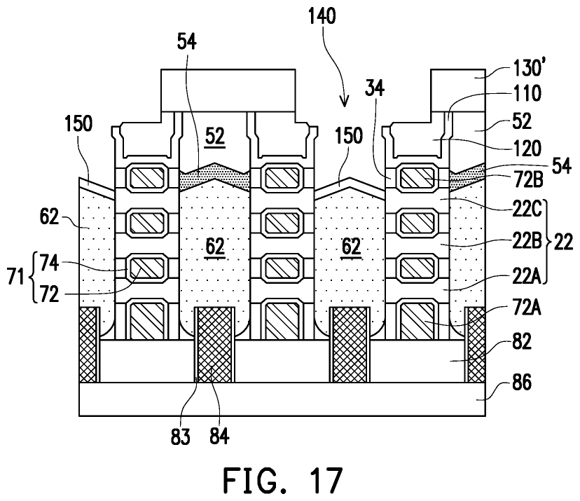

As shown in FIG. 17, a silicide layer 150 is formed on the exposed surfaces of the source and drain regions 62 inside the openings 140. In some embodiments, the material of the silicide layer 150 includes metal silicide such as cobalt silicide (CoSi), ruthenium silicide (RuSi), nickel silicide (NiSi), titanium silicide (TiSi), or a combination thereof. In one embodiment, the silicide layer 150 includes titanium silicon. In some embodiments, the silicide layer 150 may be formed by forming a metal layer over the epitaxy source and drain regions 62, thermal treating for the metal to be reacted with silicon. In one embodiment, the silicide layer 150 is formed by depositing a titanium layer and heating under about 400 Celsius degrees, and later optionally performing nitridation using ammonia plasma treatment. In some embodiments, the silicide layer 150 is only formed on the top surfaces of the exposed source and drain regions 62 since the metal only reacts with silicon in the source and drain regions 62. As seen in FIG. 17, the silicide layers 150 are in contact with the top surface of the source/drain region 62 and the second semiconductor layers 22C. In one embodiment, the silicide layer 150 has a thickness ranging from about 2 nm to about 6 nm.

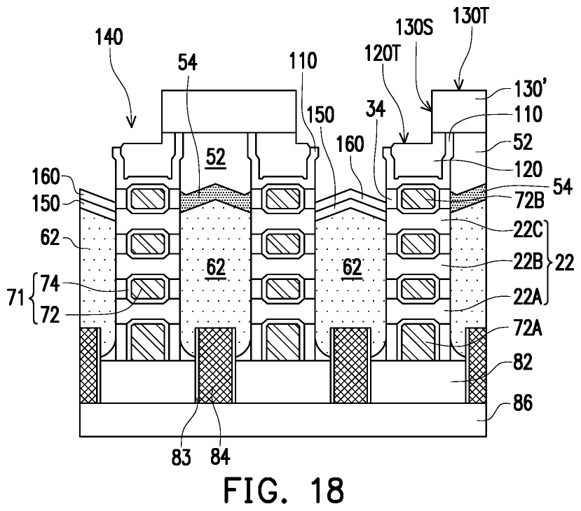

As shown in FIG. 18, a shielding layer 160 is formed on the silicide layer 150. In some embodiments, the shielding layer 160 is formed directly on the silicide layer 150 and is formed only on the silicide layer 150. In some embodiments, the shielding layer 160 is an organic material layer formed through reaction between silicide and organic molecules alkanethiol such as 1-octadecanethiol (ODT), or the like. As such, the formed shielding layer 160 includes self-assembled monolayers (SAMs) that are assembled through the specific functional group of the organic molecules having strong affinity onto the metal surface. In one embodiment, the shielding layer 160 may have a thickness in a range from about 1 nm to about 5 nm. The shielding layer 160 may function as inhibitor or suppressor for the subsequent formed liner layer.

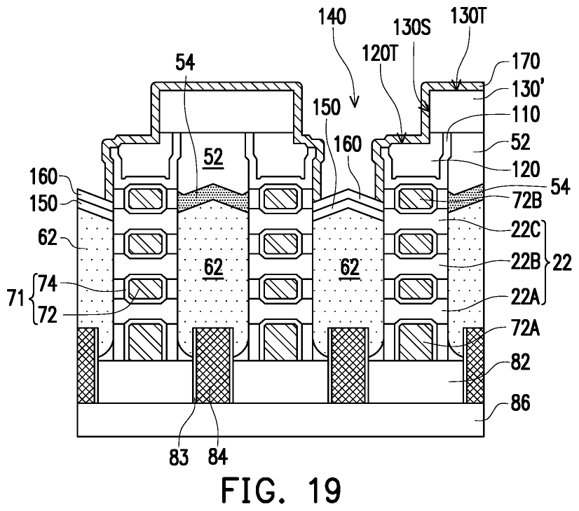

As shown in FIG. 19, in some embodiments, a liner layer 170 is formed over the patterned hard mask layer 130′ and over the openings 140. In some embodiments, the liner layer 170 is conformally formed over the openings 140, and the liner layer 170 covers the sidewalls of the openings 140 without covering the bottom surfaces of the openings 140 due to the presence of the shielding layer 160. In some embodiments, the liner layer 170 covers top surface 130T and inner sidewalls 130S of the hard mask layer 130′, the top surfaces 120T of the recessed filling layers 120, the recessed portions of the liner layers 110, but avoiding the shielding layer 160. In some embodiments, depending on the stacking design of the stacks, the liner layer 170 may cover partially the sidewalls of the lateral spacers 34 next to the gate electrodes 72B. In some embodiments, the liner layer 170 is not in direct contact with the shielding layer 160, although both may be in a close state and seen as being in touch in the figures. In some embodiments, the material of the liner layer 170 is different from that of the liner layer 110. In some embodiments, the material of the liner layer 170 is substantially the same as that of the liner layer 110. In some embodiments, the material of the liner layer 170 includes silicon oxide, SiOC, SiCN, SiOCN, AlO, AlON, ZrO, HfO, TiO, ZrAlO, ZnO, or a combination thereof. In some embodiments, the liner layer 170 is formed by PVD, CVD, ALD, or the like. In some embodiments, the liner layer 170 has a thickness ranging from about 1 nm to about 5 nm.

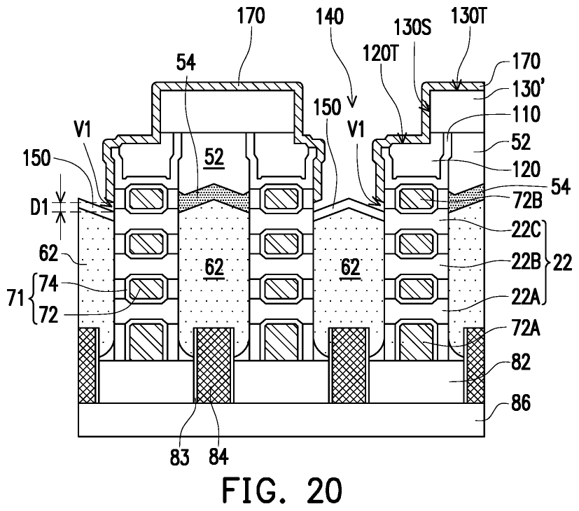

As shown in FIG. 20, the shielding layer 160 is removed. In some embodiments, the shielding layer 160 is removed through a selective removal process as the shielding layer 160 is removed without damaging the underlying silicide layer 150 and the source and rain regions 62. In some embodiments, the selective removal process includes performing a plasma dry etching process, a wet etching process, an ashing process, or a combination thereof. In some embodiments, the selective removal process includes a wet cleaning process using a cleaning solution such as sulfuric peroxide mix (SPM) under a high temperature. After removing the shielding layer 160, the silicide layer 150 is exposed and the liner layer 170 is spaced apart from the silicide layer 150 with a distance D1 ranging from about 1 nm to about 5 nm along the Z-direction (the thickness direction). That is, there is void space V1 between the liner layer 170 and the silicide layer 150.

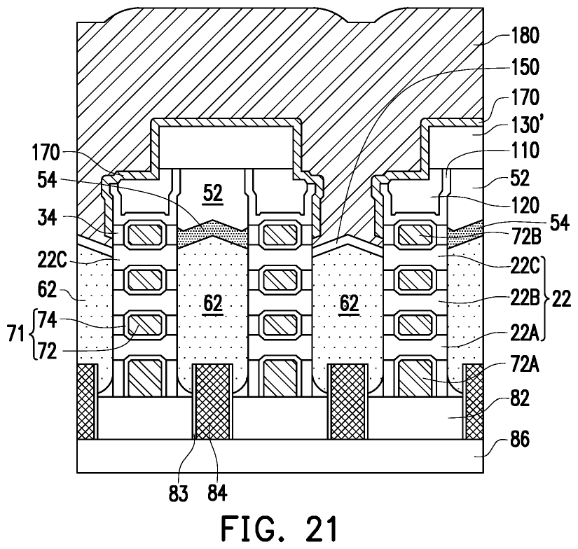

Referring to FIG. 20 and FIG. 21, a metal layer 180 is formed over the patterned hard mask layer 130′ and over the liner layer 170. In some embodiments, the metal layer 180 fully covers the liner layer 170 and fills up the openings 140. In some embodiments, the metal layer 180 filling into the openings 140 fully covers the exposed silicide layer 150 and fills up the void space V1 between the liner layer 170 and the silicide layer 150. In some embodiments, the material of the metal layer 180 includes W, Ru, Mo, Co, or the like. In other embodiments, before forming the metal layer 180, a barrier material, such as TiN, TaN, or a combination thereof, may be formed as a contact barrier.

Referring to FIG. 22 and FIG. 23, a planarization process is performed to remove the extra materials of the metal layer 180 and the liner layer 170 above the hard mask layer 130′ to form the metal contact 180C and the liner 170C. In some embodiments, the planarization process including a CMP process is performed to level surfaces of the semiconductor device structure 10, so that the top surfaces of the hard mask layer 130′, the liner 170C, and the metal contact 180C are coplanar and levelled with one another. In some embodiments, the metal contact 180C functions as the backside contact connected to the source and drain regions 62. That is, for some of the source and drain regions 62, the metal contact 180C and the metallic contact 84 are connected to two opposite sides of the source/drain terminal 62.

In some embodiments, as seen in the partial enlarged view at upper part of FIG. 22, the metal contact 180C fills up the opening(s) 140, and the metal contact 180C includes an extended portion 180CE at the bottom of the opening 140. In some embodiments, the extended portion 180CE directly contacts the silicide layer 150 and is in direct contact with the spacers 34 without having the liner there-between by filling up the void spaces V1. In some embodiments, the extended portion 180CE filled inside the space V1 has the same thickness of the distance D1, and the liner 170C is separated from the silicide layer 150 by the extended portion 180CE, as seen in FIG. 23. In some embodiments, referring to FIG. 22 and FIG. 23, the metal contact 180C is laterally surrounded by the liner 170C except the extended portion 180CE that is not covered by the liner 170C and is in direct contact with the silicide layer 150. With the extended portion 180CE, the contact area between the metal contact 180C and the silicide layer 150 is increased and the resistance is reduced, further enhancing the processing speed of the transistor and the performance of the device.

In some embodiments, as seen in the partial enlarged view at upper part of FIG. 22, the liner 170C contacts the inner sidewalls 130S of the hard mask layer 130′, the top surface 120T of the recessed filling layer 120 and the recessed liner layer 110, but the liner 170C is not in contact with the silicide layer 150. Through the liner 170C covering the recessed filling layer 120 and the recessed liner layer 110, the metal contact 180C is better isolated from the gate structures 71.

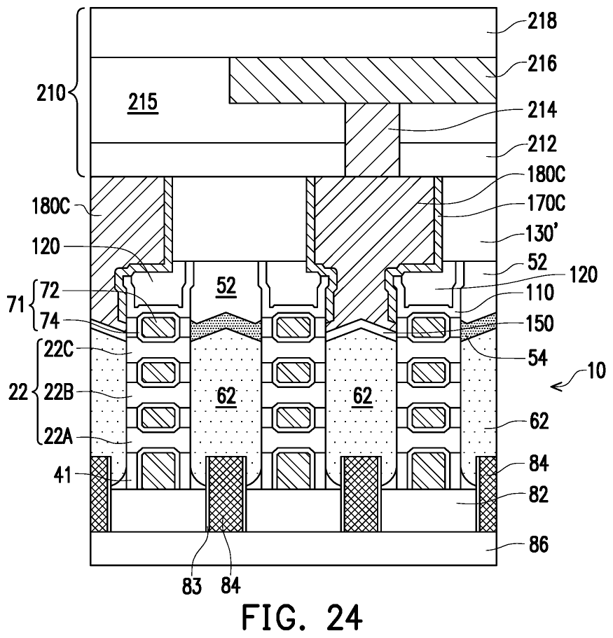

As shown in FIG. 24, further connection structure 210 is formed on the semiconductor device structure 10 for further electrical connection and power supply. In some embodiments, dielectric material layer 212 and 215 are sequentially formed to cover the metal contact 180C, the liner 170C and the hard mask layer 130′. Also, conductive via 214 and metal wirings 216 are formed inside the dielectric material layers 212 and 215, and another insulating layer 218 is formed over the dielectric material layer 215. In some embodiments, the metal wirings 216 include power rails such as super power rails, for power supply.

In some embodiments, conductive via 214 and metal wirings 216 may include a metallic material, such as Cu, W, Al, Ru, Co, Ni or the alloys thereof. In some embodiments, the material of the insulating layer 218 includes SiN, SiON, SiC or a combination thereof, and the materials of the dielectric material layer 212 and 215 include silicon oxide, PSG, BSG, BPSG, a low-k dielectric, or the like. As also shown in FIG. 24, the connection structure 210 is electrically connected with the semiconductor device structure 10 through the metal contact(s) 180C.

In some embodiments, the present disclosure relates to a semiconductor device. The device includes semiconductor channel sheets, source and drain regions and a gate structure. The semiconductor channel sheets are arranged in parallel and spaced apart from one another. The source and drain regions are disposed beside the semiconductor channel sheets. The gate structure is disposed around and surrounding the semiconductor channel sheets. The silicide layer is disposed on the source region or the drain region. A contact structure is disposed on the silicide layer on the source region or the drain region. The contact structure includes a metal contact and a liner, and the silicide layer is in contact with the metal contact, and the liner is separate from the silicide layer by the metal contact.

In some embodiments, the present disclosure relates to a semiconductor device. The device includes semiconductor channel sheets, source and drain regions and a gate structure. The semiconductor channel sheets are spaced apart from one another. The source and drain regions are disposed beside the semiconductor channel sheets. The gate structure is disposed around and surrounding the semiconductor channel sheets. The first contact structures are disposed on the source and drain regions. A silicide layer is disposed on the source region or the drain region. The second contact structure is disposed on the silicide layer on the source region or the drain region. The second contact structure and one first contact structure are located at opposite sides of the source region or the drain region. The second contact structure includes a metal contact and a liner, and the silicide layer is in contact with the metal contact, and the liner is separate from the silicide layer by the metal contact.

In some embodiments, the present disclosure relates to a method of forming a semiconductor device. Semiconductor channel sheets are formed over a substrate. Source and drain regions are formed beside the semiconductor channel sheets. A gate structure is formed over and surrounds the semiconductor channel sheets. The substrate is thinned, and an isolation cap is formed on the gate structure. A hard mask layer is formed on the isolation cap. The hard mask layer is patterned and a portion of the isolation cap is partially removed to form openings exposing the source and drain regions. A silicide layer is formed respectively on the exposed source and drain regions. A shielding layer is formed on the silicide layer. A liner layer is formed over the patterned hard mask layer and over the openings. The shielding layer is removed. Metal contacts are formed in the openings. The metal contacts contact the silicide layers without the liner layer there-between.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
semiconductor channel sheets, arranged in parallel and spaced apart from one another;
source and drain regions disposed beside the semiconductor channel sheets;
a gate structure disposed around and surrounding the semiconductor channel sheets;
a silicide layer disposed on the source region or the drain region; and
a contact structure disposed on the silicide layer on the source region or the drain region,
wherein the contact structure includes a metal contact and a liner, and the silicide layer is in contact with the metal contact, and the liner is separate from the silicide layer by the metal contact.

2. The semiconductor device of claim 1, further comprising an isolation cap disposed on the gate structure, wherein the isolation cap is separate from the metal contact through the liner located there-between.

3. The semiconductor device of claim 2, wherein the isolation cap includes a filling layer and the liner is in contact with the filling layer of the isolation cap.

4. The semiconductor device of claim 1, wherein the metal contact includes an extended portion disposed directly on the silicide layer.

5. The semiconductor device of claim 4, wherein the metal contact is laterally surrounded by the liner except for the extended portion.

6. The semiconductor device of claim 4, wherein the extended portion physically contacts the silicide layer without the liner there-between.

7. The semiconductor device of claim 1, wherein the source region or the drain region includes an epitaxial layer.

8. The semiconductor device of claim 7, wherein the source region or the drain region includes an isolation layer adjacent to the epitaxial layer.

9. A semiconductor device, comprising:
semiconductor channel sheets spaced apart from one another;
source and drain regions disposed beside the semiconductor channel sheets;
a gate structure disposed around and surrounding the semiconductor channel sheets;
first contact structures disposed on the source and drain regions;
a silicide layer disposed on the source region or the drain region; and
a second contact structure disposed on the silicide layer on the source region or the drain region,
wherein the second contact structure and one first contact structure are located at opposite sides of the source region or the drain region, the second contact structure includes a metal contact and a liner, and the silicide layer is in contact with the metal contact, and the liner is separate from the silicide layer by the metal contact.

10. The semiconductor device of claim 9, further comprising an isolation cap disposed on the gate structure, wherein the isolation cap is separate from the metal contact through the liner located there-between.

11. The semiconductor device of claim 10, wherein the isolation cap includes a filling layer and the liner is in contact with the filling layer of the isolation cap.

12. The semiconductor device of claim 9, wherein the metal contact includes an extended portion disposed directly on the silicide layer.

13. The semiconductor device of claim 12, wherein the metal contact is laterally surrounded by the liner except for the extended portion.

14. The semiconductor device of claim 12, wherein the extended portion physically contacts the silicide layer without the liner there-between.

15. The semiconductor device of claim 9, wherein the source region or the drain region includes an epitaxial layer.

16. The semiconductor device of claim 15, wherein the source region or the drain region includes an isolation layer adjacent to the epitaxial layer.

17. A method of forming a semiconductor device, comprising:
forming semiconductor channel sheets over a substrate;
forming source and drain regions beside the semiconductor channel sheets;
forming a gate structure over and surrounding the semiconductor channel sheets;
thinning the substrate;
forming an isolation cap on the gate structure;
forming a hard mask layer on the isolation cap;
patterning the hard mask layer and partially removing a portion of the isolation cap to form openings exposing the source and drain regions;
forming a silicide layer respectively on the exposed source and drain regions;
forming a shielding layer on the silicide layer;
forming a liner layer over the patterned hard mask layer and over the openings;
removing the shielding layer; and
forming metal contacts in the openings,
wherein the metal contacts contact the silicide layers without the liner layer there-between.

18. The method of claim 17, wherein forming metal contacts in the openings includes forming a metal layer on the liner layer and filling up the openings, and remove the metal layer and the liner layer above the patterned hard mask layer.

19. The method of claim 17, wherein the liner layer is formed over the openings covering the isolation cap without covering the shielding layer.

20. The method of claim 17, wherein forming the shielding layer includes forming self-assembled monolayers of an organic material.
